(19) United States
(12) Patent Application Publication
(10) Pub. No.: US 2025/0203975 A1
(43) Pub. Date: Jun. 19, 2025

(54) INTEGRATED CIRCUIT DEVICE WITH SEMICONDUCTOR STRUCTURE EXTENDING ACROSS GATE IN ISOLATON REGION

(71) Applicants: Guowei Xu, Portland, OR (US); Paul Packan, Hillsboro, OR (US); Anand S. Murthy, Portland, OR (US); Chia-Ching Lin, Portland, OR (US); Yanbin Luo, Portland, OR (US); Minwoo Jang, Portland, OR (US); Yang Zhang, Rio Rancho, NM (US); Chung-Hsun Lin, Portland, OR (US); Tao Chu, Portland, OR (US); Ting-Hsiang Hung, Beaverton, OR (US); Chiao-Ti Huang, Portland, OR (US); Feng Zhang, Hillsboro, OR (US); Robin Chao, Portland, OR (US); Kan Zhang, HILLSBORO, OR (US)

(72) Inventors: Guowei Xu, Portland, OR (US); Paul Packan, Hillsboro, OR (US); Anand S. Murthy, Portland, OR (US); Chia-Ching Lin, Portland, OR (US); Yanbin Luo, Portland, OR (US); Minwoo Jang, Portland, OR (US); Yang Zhang, Rio Rancho, NM (US); Chung-Hsun Lin, Portland, OR (US); Tao Chu, Portland, OR (US); Ting-Hsiang Hung, Beaverton, OR (US); Chiao-Ti Huang, Portland, OR (US); Feng Zhang, Hillsboro, OR (US); Robin Chao, Portland, OR (US); Kan Zhang, HILLSBORO, OR (US)

(21) Appl. No.: 18/539,709

(22) Filed: Dec. 14, 2023

(51) Int. Cl. H01L 29/08; H01L 29/06; H01L 29/417; H01L 29/423; H01L 29/66; H01L 29/775

(52) U.S. Cl. CPC H10D 62/151; H10D 30/014; H10D 30/43; H10D 30/6729; H10D 30/6735; H10D 62/121

(57) ABSTRACT

An IC device may have activation regions and an isolation region between the active regions. An active region may include one or more transistors. The IC device includes gates that are in parallel. Some of the gates are in the active regions. The other gates are in the isolation region. A source or drain region may be formed between a gate in the isolation region and a gate in a transistor in the first direction. The IC device may include one or more semiconductor structures that extend across a gate in a transistor, and the semiconductor structures may constitute a channel region of the transistor. The IC device may also include one or more semiconductor structures that extend across an individual gate in the isolation region. An insulative structure may be formed between two gates in the isolation region. The insulative structure may be over the source or drain region.

### BACKGROUND

Integrated circuit (IC) fabrication usually includes two stages. The first stage is referred to as the front end of line (FEOL). The second stage is referred to as the back end of line (BEOL). In the FEOL, individual semiconductor devices components (e.g., transistor, capacitors, resistors, etc.) can be patterned in a wafer. Non-functional regions may also be formed between functional devices in the FEOL. Non-functional regions may be used to isolate the functional devices from each other. Such non-functional regions are also referred to as isolation regions. In the BEOL, metal layers, vias, and insulating layers can be formed to get the individual components interconnected. Metal layers can be arranged at both the frontside and the backside of the semiconductor devices. Functional devices may be coupled to metal layers, e.g., a metal layer used as power plane, ground plane, or signal plane.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an IC device comprising a FEOL section and a BEOL section, according to some embodiments of the disclosure.

FIG. 2 illustrates an IC device including transistors and isolation regions, according to some embodiments of the disclosure.

FIG. 3 illustrates an IC device with semiconductor cut in an isolation region, according to some embodiments of the disclosure.

FIG. 4 illustrates an IC device with no semiconductor cut in an isolation region, according to some embodiments of the disclosure.

FIGS. 5A-5F illustrate a process of fabricating an IC device with semiconductor structures extending across gates in an isolation region, according to some embodiments of the disclosure.

FIG. 6 shows nanoribbons extending across a gate, according to some embodiments of the disclosure.

FIGS. 7A-7B are top views of a wafer and dies, according to some embodiments of the disclosure.

FIG. 8 is a side, cross-sectional view of an example IC package that may include one or more IC devices with semiconductor structures extending across gates in isolation regions, according to some embodiments of the disclosure.

FIG. 9 is a cross-sectional side view of an IC device assembly that may include components having one or more IC devices with semiconductor structures extending across gates in isolation regions, according to some embodiments of the disclosure.

FIG. 10 is a block diagram of an example computing device that may include one or more components with semiconductor structures extending across gates in isolation regions, according to some embodiments of the disclosure.

### DETAILED DESCRIPTION

The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

Many IC devices include a large array of semiconductor devices, e.g., transistors. Examples of transistors in these circuit devices include metal-oxide-semiconductor field-effect transistor (MOSFET), such as N-type metal-oxide-semiconductor (NMOS) FET (field-effect transistor), P-type metal-oxide-semiconductor (PMOS) FET, and so on. Continued scaling of transistors creates challenges for forming isolation regions between adjacent transistors. An isolation region may be located between two neighboring transistors for isolating the two transistors from each other. Source or drain regions are typically not formed in isolation regions. Currently available approaches for fabricating isolation regions usually require cutting semiconductor structures (e.g., fins, nanoribbons, etc.) in isolation regions, which may be done even before gates in the isolation regions are formed. Such approaches can cause with-in die (WID) variations in the downstream process. Gate profile and wafer topography can be impacted. For instance, gates for continuous semiconductor structures (e.g., gates in active transistors) can have different profiles from gates for cut off semiconductor structures. WID variations can result in yield issues, such as gate etch out over the isolation region. The yield issues can significantly impact the performance of the IC device.

Embodiments of the present disclosure may improve on at least some of the challenges and issues described above by providing IC devices with semiconductor structures (e.g., fins, nanoribbons, etc.) extending across gates in isolation regions. For instance, one or more semiconductor structures may extend at least from a first edge of a gate electrode in an isolation region of an example IC device to a second edge of the gate electrode. The second edge may oppose the first edge. The one or more semiconductor structure may extend beyond the gate electrode. For instance, the one or more semiconductor structures may extend through the entire gate including the gate electrode and the gate insulator or may even extend beyond the gate. An example isolation region in an IC device may be formed without semiconductor cut. For instance, the isolation region may be formed by blocking growth of source or drain region in the region. Without semiconductor cut, the profiles of gates in the isolation region and gates in transistors would be the same or substantially similar and therefore, WID variations can be reduced or even eliminated.

In various embodiments of the present disclosure, an IC device may have an isolation region between active transistors. The IC device includes gates that are stacked in parallel. A gate may include a conductive structure and a dielectric layer wrapping around the conductive structure. Some of the gates are in the active transistors. Some other gates are in the isolation region. A source or drain region of a transistor may be formed between a gate in the isolation region and a gate in the transistor. The IC device may include one or more semiconductor structures that extend across a gate in every active transistor, and the semiconductor structures may constitute a channel region of the active transistor. Same as the gates in the active transistors, every gate in the isolation region also has semiconductor structures that extend across the gate. An insulative structure may be formed between two adjacent gates in the isolation region. The insulative structure may be over the source or drain region. In some cases, a gate in the isolation region may be a dummy gate that is not functional, while a gate in an active region is an active gate that is functional. An active gate may be coupled to a metal layer, which may be a signal plane. A dummy gate may be insulated from the metal layer by one or more electrical insulators.

To form the IC device, the gates and a semiconductor stack may be formed. The gates may be stacked over each other in a first direction. The semiconductor stack may include semiconductor structures stacked over each other in a second direction that is perpendicular to the first direction. Each semiconductor structure may extend across some or all the gates. The semiconductor structures may be separated from each other by a semiconductor material. A first portion of the semiconductor stack may be removed to form a first opening region between a first gate and a second gate. A second portion of the semiconductor stack may be removed to form a second opening region between the second gate and a third gate. A source or drain region may be formed in the first opening region, while an insulative structure may be formed in the second opening region. A mask may be used to block the second opening region while having the first opening region exposed in the process of forming the source or drain region. The mask may also block opening regions for forming source or drain regions of other transistors, e.g., transistors of the opposite type from the transistor including the source or drain region. After the insulative structure is formed, the semiconductor material may be replaced with a conductive material.

It should be noted that, in some settings, the term “nanoribbon” has been used to describe an elongated semiconductor structure that has a substantially rectangular transverse cross-section (e.g., a cross-section in a plane perpendicular to the longitudinal axis of the structure), while the term “nanoribbon” has been used to describe a similar structure but with a substantially circular or square transverse cross-sections. In the following, a single term “nanoribbon” is used to describe an elongated semiconductor structure independent of the shape of the transverse cross-section. Thus, as used herein, the term “nanoribbon” is used to cover elongated semiconductor structures that have substantially rectangular transverse cross-sections (possibly with rounded corners), elongated semiconductor structures that have substantially square transverse cross-sections (possibly with rounded corners), elongated semiconductor structures that have substantially circular or elliptical/oval transverse cross-sections, as well as elongated semiconductor structures that have any polygonal transverse cross-sections.

In the following, some descriptions may refer to a particular source or drain (S/D) region or contact being either a source region/contact or a drain region/contact. However, unless specified otherwise, which region/contact of a transistor or diode is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a substrate that includes electrically conductive interconnect structures for providing electrical connectivity between different IC components. Metal layers described herein may also be referred to as “interconnect layers” to clearly indicate that these layers include electrically conductive interconnect structures which may, but do not have to be, metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−10%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−8% of a target value, e.g., within +/−5% of a target value or within +/−2% of a target value, based on the context of a particular value as described herein or as known in the art. Also, the term “or” refers to an inclusive “or” and not to an exclusive “or.”

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

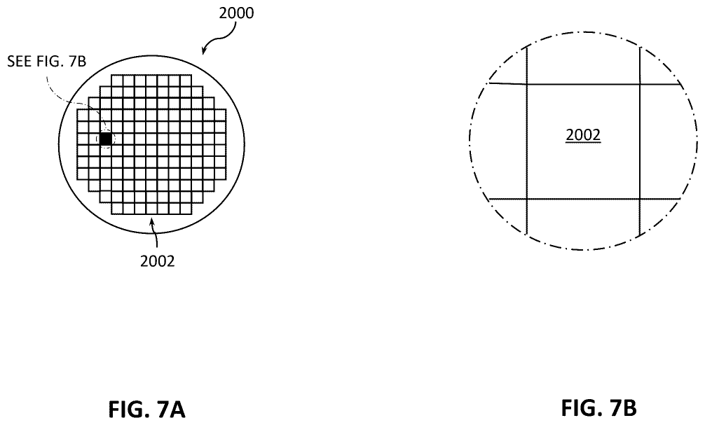

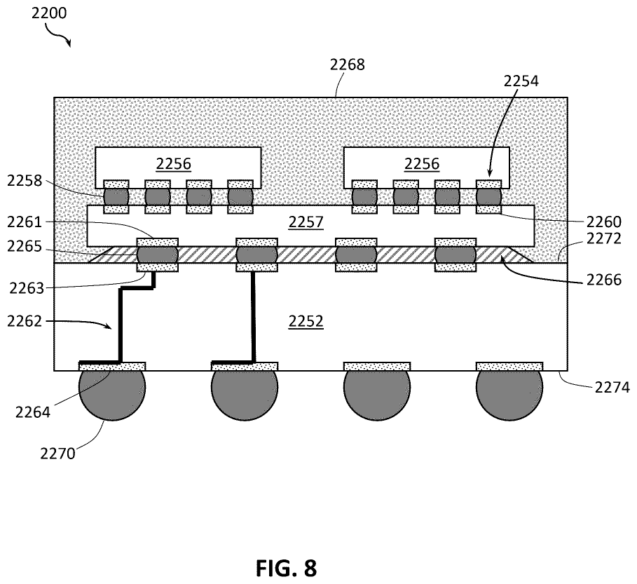

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 7A-7B, such a collection may be referred to herein without the letters, e.g., as “FIG. 8.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of semiconductor devices with semiconductor structures extending across gates in isolation regions as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices with semiconductor structures extending across gates in isolation regions as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

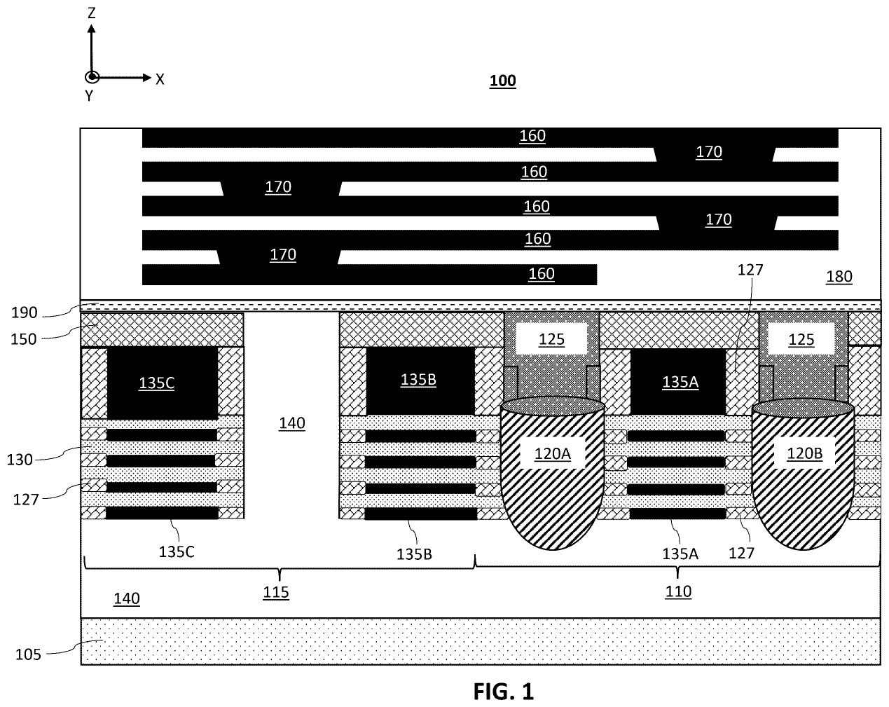

FIG. 1 illustrates an IC device 100 comprising an FEOL section and a BEOL section, according to some embodiments of the disclosure. In some embodiments, the IC device 100 may be formed through a complementary metal-oxide semiconductor (CMOS) fabrication process. For the purpose of illustration, FIG. 1 shows a cross-sectional view of the IC device 100 in the X-Z plane. The FEOL section includes components patterned and formed in FEOL. In the embodiments of FIG. 1, the FEOL section a support structure 105, semiconductor structures 120A and 120B (collectively referred to as “semiconductor structures 120” or “semiconductor structure 120”), electrodes 125 (individually referred to as “electrode 125”), dielectric structures 127 (individually referred to as “dielectric structure 127”), semiconductor structures 130 (individually referred to as “semiconductor structure 130”), electrodes 135A-135C (collectively referred to as “electrodes 135” or “electrode 135”), an electrical insulator 140, and spacers 150 (individually referred to as “spacer 150”). Some of the components in the FEOL section constitute a transistor 110. The BEOL section includes components patterned and formed in BEOL. In the embodiments of FIG. 1, the BEOL section includes metal layers 160, vias 170, another electrical insulator 180, and a contact layer 190.

In other embodiments, the FEOL section, the BEOL section, or the IC device 100 may include fewer, more, or different components. For example, the IC device 100 may include one or more semiconductor devices not shown in FIG. 1. As another example, the IC device 100 may include a different number of semiconductor structures, electrodes, metal layers, vias, etc. Also, the shapes, dimensions, and locations of the components of the IC device 100 shown in FIG. 1 are for illustration. The components of the IC device 100 may have different shapes, dimensions, or locations. Connections or electrical coupling between the components of the IC device 100 may also be different.

The support structure 105 may be any suitable structure, such as a substrate, a die, a wafer, or a chip. The support structure 105 may, e.g., be the wafer 2000 of FIG. 7A, discussed below, and may be, or be included in, a die, e.g., the singulated die 2002 of FIG. 7B, discussed below. Semiconductor devices may be built over the support structure 105. Examples of the semiconductor devices include transistors (e.g., the transistor 110), resistors, capacitors, and so on. In some embodiments, the support structure 105 may be a semiconductor substrate composed of semiconductor material systems including, for example, N-type or P-type materials systems, and, in some embodiments, the channel region, described herein, may be a part of the support structure 105. In some embodiments, the semiconductor substrate may be a crystalline substrate formed using a bulk silicon or a silicon-on-insulator substructure. In other embodiments, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of Group III-V, Group II-VI, or Group IV materials. In some embodiments, the substrate may be non-crystalline. In some embodiments, the support structure 105 may be a printed circuit board (PCB) substrate. One or more transistors, such as the transistor may be built on the support structure 105.

Although a few examples of materials from which the support structure 105 may be formed are described here, any material that may serve as a foundation upon which an IC may be built falls within the spirit and scope of the present disclosure. In various embodiments, the support structure 105 may include any such substrate, possibly with some layers and/or devices already formed thereon, not specifically shown in the present figures. As used herein, the term “support” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the support structure 105 may provide material “support” in that, e.g., the IC devices/structures described herein are build based on the semiconductor materials of the support structure 105. However, in some embodiments, the support structure 105 may provide mechanical support.

The semiconductor structures 120 may have crystal structures. A semiconductor structure 120 may be formed through an epitaxial growth process, in which a crystal material may be formed with one or more well-defined orientations with respect to a crystal substrate after the material is deposited onto the crystal substrate. The semiconductor structures 120 may also be referred to as epitaxial structures or epitaxial semiconductor structures. The crystal substrate used for epitaxial growth may be a die or wafer (not shown in FIG. 1). The crystal direction of the epitaxial structures may be determined based on a crystal direction in the crystal substrate.

The semiconductor structures 130 may be semiconductor structures having non-planar shapes. In some embodiments, the semiconductor structures 130 are nanoribbons. A semiconductor structure 130 may have a longitudinal axis along the X axis. The semiconductor structure 130 may also have a transverse cross-section that is perpendicular to the longitudinal axis. The transverse cross-section may be in the Y-Z plane. The dimension of the semiconductor structure 120 along the X axis may be greater (e.g., significantly greater) than the dimension of the semiconductor structure 120 along the Y axis or along the Z axis. In other embodiments, the semiconductor structures 130 may have other non-planar shapes, such as fins. In yet other embodiments, the semiconductor structures 130 may be planar structurers.

The two semiconductor structures 120 and the semiconductor structures 130 between the two semiconductor structures 120 may be semiconductor regions in transistors. In an example, the semiconductor structure 120A may constitute a source region of the transistor 110. The semiconductor structure 120B may constitute a drain region of the transistor 110. In another example, the semiconductor structure 120A may be a drain region of the transistor 110, while the semiconductor structure 120B may be a source region of the transistor 110. Portions of the semiconductor structures 130 between the source region and drain region may constitute the channel region of the transistor 110.

The channel region may include one or more channel materials. A channel material may be composed of semiconductor material systems including, for example, N-type or P-type materials systems. In some embodiments, the channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a compound semiconductor with a first sub-lattice of at least one element from Group III of the periodic table (e.g., Al, Ga, In), and a second sub-lattice of at least one element of group V of the periodic table (e.g., P, As, Sb). In some embodiments, the channel material may include a compound semiconductor with a first sub-lattice of at least one element from Group II of the periodic table (e.g., Zn, Cd, Hg), and a second sub-lattice of at least one element of Group IV of the periodic table (e.g., C, Si, Ge, Sn, Pb). In some embodiments, the channel material is an epitaxial semiconductor material deposited using an epitaxial deposition process. The epitaxial semiconductor material may have a polycrystalline structure with a grain size between about 2 nanometers and 100 nanometers, including all values and ranges therein.

For some example N-type transistor embodiments (i.e., for the embodiments where the transistor is an NMOS transistor or an N-type TFET), the channel material may advantageously include a III-V material having a high electron mobility, such as, but not limited to InGaAs, InP, InSb, and InAs. For some such embodiments, the channel material may be a ternary III—V alloy, such as InGaAs, GaAsSb, InAsP, or InPSb. For some InxGa1-xAs fin embodiments, In content (x) may be between 0.6 and 0.9, and may advantageously be at least 0.7 (e.g., In0.7Ga0.3As). In some embodiments with highest mobility, the channel material may be an intrinsic III-V material, i.e., a Ill-V semiconductor material not intentionally doped with any electrically active impurity. In alternate embodiments, a nominal impurity dopant level may be present within the channel material, for example to further fine-tune a threshold voltage Vt, or to provide HALO pocket implants, etc. Even for impurity-doped embodiments however, impurity dopant level within the channel material may be relatively low, for example below 10¹⁵ dopant atoms per cubic centimeter (cm−3), and advantageously below 10¹³ cm³. These materials may be amorphous or polycrystalline, e.g., having a crystal grain size between 0.5 nanometers and 100 nanometers.

For some example P-type transistor embodiments (i.e., for the embodiments where the transistor is a PMOS transistor or a P-type TFET), the channel material may advantageously be a Group IV material having a high hole mobility, such as, but not limited to Ge or a Ge-rich SiGe alloy. For some example embodiments, the channel material may have a Ge content between 0.6 and 0.9, and advantageously may be at least 0.7. In some embodiments with highest mobility, the channel material may be intrinsic III-V (or IV for P-type devices) material and not intentionally doped with any electrically active impurity. In alternate embodiments, one or more nominal impurity dopant levels may be present within the channel material, for example to further set a threshold voltage (Vt), or to provide HALO pocket implants, etc. Even for impurity-doped embodiments however, impurity dopant level within the channel portion is relatively low, for example below 10¹⁵ cm⁻³, and advantageously below 10¹³ cm⁻³. These materials may be amorphous or polycrystalline, e.g., having a crystal grain size between 0.5 nanometers and 100 nanometers.

In some embodiments, the channel material may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, aluminium zinc oxide, or tungsten oxide. In general, for a thin-film transistor (TFT), the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminium gallium nitride, indium phosphite, black phosphorus, zinc sulfide, indium sulfide, gallium sulfide, each of which may possibly be doped with one or more of gallium, indium, aluminium, fluorine, boron, phosphorus, arsenic, nitrogen, tantalum, tungsten, and magnesium, etc. In some embodiments, a thin-film channel material may be deposited at relatively low temperatures, which allows depositing the channel material within the thermal budgets imposed on back-end fabrication to avoid damaging other components, e.g., front end components such as logic devices.

As noted above, the channel material may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors.

IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃(ZnO)₅. Another example form of IGZO has an indium:gallium:zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminium or nitrogen.

The source region and the drain region are connected to the channel region. The source region and the drain region each include a semiconductor material with dopants. In some embodiments, the source region and the drain region have the same semiconductor material, which may be the same as the channel material of the channel region. A semiconductor material of the source region or the drain region may be a Group IV material, a compound of Group IV materials, a Group III/V material, a compound of Group III/V materials, a Group II/VI material, a compound of Group II/VI materials, or other semiconductor materials. Example Group II materials include zinc (Zn), cadmium (Cd), and so on. Example Group III materials include aluminium (AI), boron (B), indium (In), gallium (Ga), and so on. Example Group IV materials include silicon (Si), germanium (Ge), carbon (C), etc. Example Group V materials include nitrogen (N), phosphorus (P), arsenic (As), antimony (Sb), and so on. Example Group VI materials include sulfur(S), selenium (Se), tellurium (Te), oxygen (O), and so on. A compound of Group IV materials can be a binary compound, such as SiC, SiGe, and so on. A compound of Group III/V materials can be a binary, tertiary, or quaternary compound, such as GaN, InN, and so on. A compound of Group II/VI materials can be a binary, tertiary, or quaternary compounds, such as CdSe, CdS, CdTe, ZnO, ZnSe, ZnS, ZnTe, CdZnTe, CZT, HgCdTe, HgZnTe, and so on.

In some embodiments, the dopants in the source region and the drain region are the same type. In other embodiments, the dopants of the source region and the drain region may be different (e.g., opposite) types. In an example, the source region has N-type dopants and the drain region has P-type dopants. In another example, the source region has P-type dopants and the drain region has N-type dopants. Example N-type dopants include Te, S, As, tin (Sn), Si, Ga, Se, S, In, Al, Cd, chlorine (CI), iodine (I), fluorine (F), and so on. Example P-type dopants include beryllium (Be), Zn, magnesium (Mg), Sn, P, Te, lithium (Li), sodium (Na), Ga, Cd, and so on.

In some embodiments, the source region and the drain region may be highly doped, e.g., with dopant concentrations of about 1·10²¹ cm⁻³, in order to advantageously form Ohmic contacts with the respective S/D contacts (also sometimes interchangeably referred to as “S/D electrodes”), although these regions may also have lower dopant concentrations and may form Schottky contacts in some implementations. Irrespective of the exact doping levels, the source region and the drain region may be the regions having dopant concentration higher than in other regions, e.g., higher than a dopant concentration in the channel region, and, therefore, may be referred to as “highly doped” (HD) regions.

The channel region may include one or more semiconductor materials with doping concentrations significantly smaller than those of the source region and the drain region. For example, in some embodiments, the channel material of the channel region may be an intrinsic (e.g., undoped) semiconductor material or alloy, not intentionally doped with any electrically active impurity. In alternate embodiments, nominal impurity dopant levels may be present within the channel material, for example to set a threshold voltage Vt, or to provide HALO pocket implants, etc. In such impurity-doped embodiments however, impurity dopant level within the channel material is still significantly lower than the dopant level in the source region and the drain region, for example below 10¹⁵ cm⁻³ or below 10¹³ cm⁻³. Depending on the context, the term “S/D terminal” may refer to a S/D region or a S/D contact or electrode of a transistor.

The two electrodes 125 are over the two semiconductor structures 120, respectively. Each electrode 125 may be a source electrode or a drain electrode of the transistor 110. A source electrode is an electrode over a source region. A drain electrode is an electrode over a drain region. The electrode 125 may be coupled to a power source for delivering power to the source or drain region. In some embodiments, the electrodes 125 may be at different electrical potentials during the operation of the IC device. One of the electrodes 125 may be coupled to a power plane, and the other one of the electrodes 125 may be coupled to a ground plane. Each electrode 125 includes one or more electrically conductive materials, such as metals. Examples of metals in the electrode 145A and the electrode 145B may include, but are not limited to, ruthenium (Ru), copper (Cu), cobalt (Co), palladium (Pd), platinum (Pt), nickel (Ni), and so on.

The transistor 110 also includes a gate that is over or wraps around at least a portion of the channel region. The gate may include one or more gate electrodes and one or more gate insulators. A gate electrode can be coupled to a gate terminal that controls gate voltages applied on the transistor 110. The gate electrode may include one or more gate electrode materials, where the choice of the gate electrode materials may depend on whether the transistor is a P-type transistor or an N-type transistor. For a P-type transistor, gate electrode materials that may be used in different portions of the gate electrode may include, but are not limited to, metal (e.g., ruthenium, palladium, platinum, cobalt, nickel, etc.), conductive metal oxides (e.g., ruthenium oxide, etc.), other types of conductive materials, or some combination thereof. For an N-type transistor, gate electrode materials that may be used in different portions of the gate electrode, but are not limited to, hafnium, zirconium, titanium, tantalum, aluminium, alloys of these metals, and carbides of these metals (e.g., hafnium carbide, zirconium carbide, titanium carbide, tantalum carbide, and aluminium carbide). In some embodiments, the gate electrode may include a stack of a plurality of gate electrode materials, where zero or more materials of the stack are work function materials and at least one material of the stack is a fill metal layer. Further materials/layers may be included next to the gate electrode for other purposes, such as to act as a diffusion barrier layer or/and an adhesion layer. In some embodiments, the gate electrodes of transistors of different types may have different work function materials. For instance, one or more work function materials in the gate electrode of an N-type transistor are different from one or more work function materials in the gate electrode of a P-type transistor.

The gate insulator separates at least a portion of the channel region from the gate electrode so that the channel region is insulated from the gate electrode. In some embodiments, the gate insulator may wrap around at least a portion of the channel region. The gate insulator may also wrap around at least a portion of the source region or the drain region. At least a portion of the gate insulator may be wrapped around by the gate electrode. The gate insulator includes an electrical insulator, such as a dielectric material, hysteretic material, and so on. Examples of dielectric materials include oxide (e.g., silicon-based oxides, metal oxides, etc.), nitride, carbide, and so on. Examples of hysteretic materials include ferroelectric materials, antiferroelectric materials, etc.

In the embodiments of FIG. 1, the electrode 135A may be the gate electrode of the transistor 110. The electrode 135A is referred to as an active gate electrode, i.e., a gate electrode that is functional during operation of the IC device. The semiconductor structures 130 in the channel region of the transistor 110 extend across the electrode 135A along the X axis. As shown in FIG. 1, each semiconductor structure 130 extends across the entire electrode 135A along the X axis. A semiconductor structure 130 is over the electrode 135A as well as the dielectric structures 127 connected to the electrode 135A along the Z axis. The length of semiconductor structure 130 along the Z axis may be the same as or substantially similar to the total length of the electrode 135A plus the dielectric structures 127 connected to the electrode 135A. Even though not shown in FIG. 1, the electrode 135A may be connected to a metal layer (e.g., a metal layer 160 at the frontside or a backside metal layer), which may be a signal plane, power plane, or ground plane. In some embodiments, the electrode 135A is connected to a via that is coupled to a metal interconnect in the metal layer.

In some embodiments, the dielectric structures 127 constitute gate insulators of the transistor 110. The dielectric structures 127 may be electrically insulative. A dielectric structure 127 may surround at least part of a semiconductor structure 130. The dielectric structure 127 may separate the semiconductor structure 130 from the corresponding gate electrode. In some embodiments, a dielectric structure 127 may include one or more high-k dielectric materials. A high-k dielectric material may have dielectric constants higher than the dielectric constant of silicon dioxide. The dielectric constant of silicon dioxide may be approximately 3.9. Examples of high-k dielectric materials include aluminium oxide, zirconium dioxide, hafnium (IV) oxide, silicon nitride, tantalum pentoxide, lead zirconate titanate, and so on.

The electrical insulator 140 and spacers 150 are also electrically insulative and may include electrical insulators, such as the ones described above. The electrical insulator 140 and spacers 150 may separate components in the IC device 100 from each other so that these components are not undesirably coupled to each other. For instance, the electrical insulator 140 may separate some of the electrodes 135 from the support structure 105. The spacers 150 may separate some or all of the electrodes 135 from the semiconductor structures 120. The spacers 150 may also separate some or all of the electrodes 135 from some or all of the electrodes 125. Also, the spacer 150 may insulate some or all of the electrodes 135 from other components in the IC device 100, e.g., the electrodes 125, the contact layer 190, and so on. In some embodiments, a dielectric structure 127, the electrical insulator 140, and the spacer 150 includes one or more insulating materials, such as the electrical insulators described above.

In some embodiments, a spacer 150 may include a dielectric material that is different from the dielectric material(s) in the dielectric structures 127. In an example, a spacer 150 may include one or more low-k dielectric materials. A low-k dielectric material may have dielectric constants lower than the dielectric constant of silicon dioxide. Examples of low-k dielectric materials include silicon-based low-k materials (e.g., fluorine doped silicon dioxide, carbon-doped silicon oxide, silicon oxycarbides, etc.), polymers, silsesquioxane (SSQ)-based materials (e.g., hydrogen-SSQ, methyl-SSQ, etc.), and so on. In some embodiments, the spacers 150 may include the same material as the electrical insulator 140.

The electrodes 135B and 135C are in an isolation region 115 of the IC device 100. The isolation region 115 may also include the dielectric structures 127 connected to the electrodes 135B and 135C, two groups of the semiconductor structures 130, the portion of the electrical insulator 140 between the electrodes 135B and 135C, and the spacers over the electrodes 135B and 135C. The isolation region 115 may isolate the transistor 110 from other functional devices in the IC device 100. The other functional devices may be other transistors, capacitors, inductors, and so on. The electrodes 135B and 135C may be dummy electrodes, i.e., electrodes that are not functional. The electrodes 135B and 135C may be added for providing the isolation, balancing capacitance in the IC device 100, maintaining symmetry of circuit layout, facilitating fabrication process, other purposes, or some combination thereof. The electrodes 135B and 135C may be insulated from the metal layer(s) coupled to the electrode 135A. For instance, the electrodes 135B and 135C are separated from the metal layer(s) by one or more electrical insulators, e.g., electrical insulator 140, spacers 150, electrical insulator 180, and so on.

In some embodiments, no transistors are formed with the electrode 135B or 135C. In some embodiments, the electrodes 135B and 135C may have the same or substantially similar profiles as the electrode 135A. A group of semiconductor structures extend across the electrode 135B and the dielectric structures 127 connected to the electrode 135B. Another group of semiconductor structures extend across the electrode 135C and the dielectric structures 127 connected to the electrode 135C. The three electrodes 135 may have the same or substantially similar contour, shape, size, and material. In some embodiments, the electrodes 135B and 135C may be formed by the same process as the electrode 135A.

Even though FIG. 1 shows a single transistor, the IC device 100 may include one or more other transistors. Examples of transistors in the IC device 100 may include FET, such as metal-oxide-semiconductor FET (MOSFET), tunnel FET (TFET), fin-based transistor (e.g., FinFET), nanoribbon-based transistor, gate-all-around (GAA) transistor, other types of FET, or some combination thereof. In some embodiments, the IC device 100 may include one or more N-type transistors (e.g., NMOS transistors) and one or more P-type transistors (e.g., PMOS transistors). For instance, the IC device 100 may include another transistor that is arranged over the transistor 110 along the Y axis. The other transistor may be of the opposite type from the transistor 110. In an example, the transistor 110 may be an N-type transistor, while the other transistor is a P-type transistor. In another example, the transistor 110 may be a P-type transistor, while the other transistor is an N-type transistor. The gate electrode (i.e., the electrode 135A) of the transistor 110 may include a different work function material from the gate electrode of the other transistor. The gate electrode of the two transistors may contact each other.

The metal layers 160 are stacked over the support structure 105 and transistors (e.g., the transistor 110) along the Z axis. In some embodiments, the metal layers 160 are frontside metal layers that are arranged at the frontside of the support structure 105. The IC device 100 may also include one or more backside metal layers (not shown in FIG. 1) at the backside of the support structure 105. A metal layer 160 may include one or more metal lines, which are also referred to as interconnects. A metal line may have a longitudinal axis, which may be along the X axis or Y axis. In some embodiments, the metal lines in the same metal layer 160 may be in parallel. The metal lines in two adjacent metal layers may be perpendicular to each other. A metal layer 160 may provide power or signal to an electrode 125 or 135 of the transistor 110. The metal layers 160 may be coupled with other devices than the transistor 110, such as diodes, power sources, resistors, capacitors, inductors, sensors, transceivers, receivers, antennas, and so on. The metal layers 160 may be used to deliver power or signal to such devices. In some embodiments, the metal layer 160 that is closest to the support structure 105 may be referred to as M0, the next metal layer 160 may be referred to as M1, and so on.

As shown in FIG. 1, the metal layers 160 may be coupled to each other using the vias 170. A via 170 may be connected to two or more metal layers 160 and have a longitudinal axis perpendicular to the metal layers 160. The electrical connections between the metal layers 160 may be different from the electrical connections shown in FIG. 1. Also, even though not shown in FIG. 1, the IC device 100 may include other vias that couple one or more metal layers 160 to an electrode 125 or the electrode 135A. In an example, one of the electrodes 125 may be coupled to a metal interconnect in the metal layers 160 that functions as a power plane, the other one of the electrodes 125 may be coupled to a metal interconnect in the metal layers 160 that functions as a ground plane, and the electrode 135A may be coupled to a metal interconnect in the metal layers 160 that functions as a signal plane. The metal interconnects for the power plane, ground plane, and signal plane may be separated from each other by the electrical insulator 180. The electrical insulator 180 surrounds the metal layers 160 and vias 170. The electrical insulator 180 may include one or more electrically insulating materials, such as a dielectric material, hysteretic material, and so on.

The contact layer 190 may facilitate bonding or coupling of the BEOL section of the IC device 100 with the rest of the IC device 100. The contact layer 190 may include a bonding material, e.g., glue. In some embodiments, the contact layer 190 may include one or more electrically conductive structures for coupling one or more metal layers 160 to other components of the IC device, such as one or more electrodes 125 and 135.

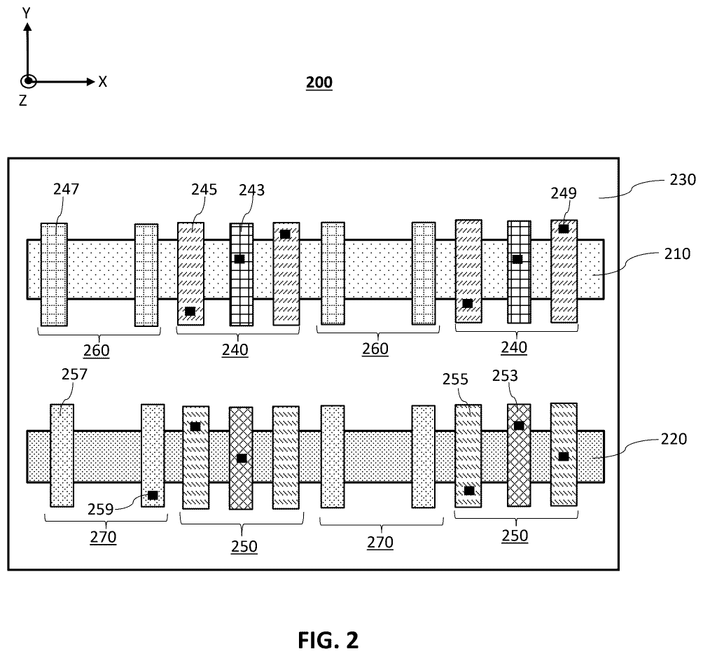

FIG. 2 illustrates an IC device including transistors 240 and 250 and isolation regions 260 and 270, according to some embodiments of the disclosure. An example of the IC device 200 (or part of the IC device 200) may be the IC device 100 in FIG. 1. As shown in FIG. 2, the IC device 200 also includes a support structure 210, another support structure 220, and an electrical insulator 230. The transistors 240 (individually referred to as “transistor 240”) and the isolation regions 260 (individually referred to as “isolation region 260”) are associated with the support structure 210. The transistors 250 (individually referred to as “transistor 250”) and the isolation regions 270 (individually referred to as “isolation region 270”) are associated with the support structure 220.

In some embodiments, the IC device 200 may be used in a memory device, such as SRAM, DRAM, etc. The IC device 200 may be a memory cell. In other embodiments, the IC device 200 may be used in a logic device. The IC device 200 may be a logic cell. For the purpose of illustration and simplicity some components of the IC device 200 are not shown in FIG. 2. Also, the IC device 200 may include fewer, more, or different components. For instance the IC device 200 may include a different number of transistor 240, transistor 250, isolation region 260, or isolation region 270.

The support structure 210 or 220 may include one or more semiconductor materials. In some embodiments, the support structure 210 or 220 may be a semiconductor substrate based on which the transistors 240 or 250 (e.g., semiconductor regions in the transistors 240 or 250) can be formed. In some embodiments, the support structures 210 and 220 may include opposite types of semiconductors. For example, the support structure 210 may be an N-type semiconductor substrate, while the support structure 210 may be a P-type semiconductor substrate. In another example, the support structure 210 may be an P-type semiconductor substrate, while the support structure 210 may be a N-type semiconductor substrate. The support structure 210 or 220 may be an embodiment of the support structure 105 in FIG. 1.

The support structures 210 and 220 (or the transistors 240 and 250) may be partially or wholly surrounded by the electrical insulator 230. The electrical insulator 230 may separate and insulate semiconductor components or conductive components in the support structures 210 and 220 (or the transistors 240 and 250). The electrical insulator 230 may include one or more electrical insulative materials, such as a dielectric material, hysteretic material, and so on.

In some embodiments, the transistors 240 may be the same type of transistor as each other, and the transistors 250 may be the same type of transistor as each other. The transistors 240 may be of the opposite type from the transistors 250. For example, the transistors 240 may be PMOS transistors, while the transistors 250 may be NMOS transistors. As another example, transistors 240 may be NMOS transistors, while the transistors 250 may be PMOS transistors. A transistor 240 or 250 may be a MOSFET, such as P-MOSFET or N-MOSFET.

Each transistor 240 includes a gate 243 over a channel region along the Z axis, an electrode 245 over a source region along the Z axis, and another electrode 245 over a drain region along the Z axis. The gate 243 is between the two electrodes 245. An example of the gate 243 may be the electrode 135A and dielectric structures 127 connected to the electrode 135A in FIG. 1. Each gate 243 or electrode 245 is connected to a conductive structure 249. A conductive structure 249 may have a longitudinal axis along the Z axis and a transverse cross-section in a X-Y plane The conductive structure 249. The dimension of the conductive structure 249 along the Z axis may be significantly larger than the dimension of the conductive structure 249 along the X or Y axis. A conductive structure 249 may be a via or pin that couples the gate 243 or electrode 245 to a metal layer. The metal layer may include a power plane, ground plane, or signal plane.

Each transistor 240 is adjacent to an isolation region 260. One of the isolation regions 260 is between the two transistor 240. The isolation regions 260 can physically or electrically isolate the transistor 240. In some embodiments, the isolation regions 260 reduce or even eliminate impact of the transistors on each other or on other transistors. Each isolation region 260 includes two gates 247. The gates 247 may be dummy gates. In some embodiments, the gates 247 are floating, e.g., the gates 247 are not coupled to any metal layers, power plane, ground plane, or signal plane. Each gate 247 may have the same or substantially similar profile as the gate 243. In some embodiments, the gates 247 are formed in the same process as the gate 243. Even though the gates 247 are not connected to any conductive structure 249 in FIG. 2, a gate 247 may be connected to a conductive structure 249 in other embodiments. Even though each isolation region 260 includes two gates 247 in FIG. 2, an isolation region may include a different number of gates 247 in other embodiments. An example of the isolation regions 260 may be the isolation region 115 in FIG. 1.

Each transistor 250 includes a gate 253 over a channel region along the Z axis, an electrode 255 over a source region along the Z axis, and another electrode 255 over a drain region along the Z axis. The gate 253 is between the two electrodes 255. An example of the gate 253 may be the electrode 135A and dielectric structures 127 connected to the electrode 135A in FIG. 1. Each gate 253 or electrode 255 is connected to a conductive structure 259. A conductive structure 249 may have a longitudinal axis along the Z axis and a transverse cross-section in a X-Y plane The conductive structure 249. The dimension of the conductive structure 249 along the Z axis may be significantly larger than the dimension of the conductive structure 249 along the X or Y axis. The conductive structure 259 may be a via or pin that couples the gate 253 or electrode 255 to a metal layer. The metal layer may include a power plane, ground plane, or signal plane.

Each transistor 250 is adjacent to an isolation region 270. One of the isolation regions 270 is between the two transistor 250. The isolation regions 270 can physically or electrically isolate the transistor 250. In some embodiments, the isolation regions 270 reduce or even eliminate impact of the transistors on each other or on other transistors. Each isolation region 270 includes two gates 257. The gates 257 may be dummy gates. In some embodiments, the gates 257 are floating, e.g., the gates 257 are not coupled to any metal layers, power plane, ground plane, or signal plane. Each gate 257 may have the same or substantially similar profile as the gate 253. In some embodiments, the gates 257 are formed in the same process as the gate 253. Even though the gates 257 are not connected to any conductive structure 259 in FIG. 2, a gate 257 may be connected to a conductive structure 259 in other embodiments. Even though each isolation region 270 includes two gates 257 in FIG. 2, an isolation region may include a different number of gates 257 in other embodiments. An example of the isolation regions 270 may be the isolation region 115 in FIG. 1.

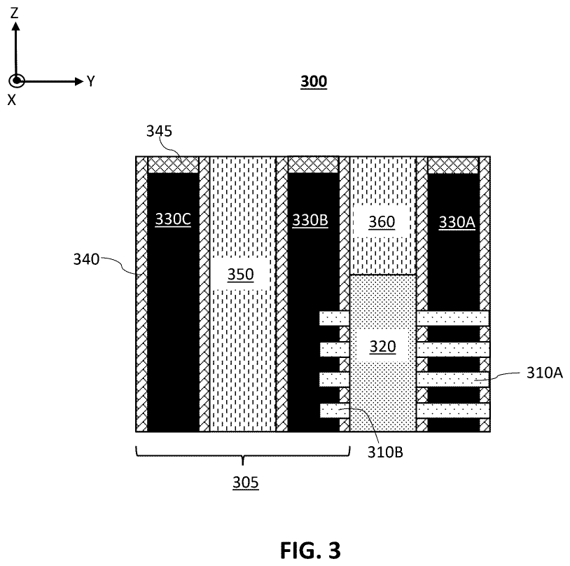

FIG. 3 illustrates an IC device 300 with semiconductor cut in an isolation region 305, according to some embodiments of the disclosure. The IC device 300 includes semiconductor structures 310A (individually referred to as “semiconductor structure 310A”), semiconductor structures 310B (individually referred to as “semiconductor structure 310B”), another semiconductor structure 320, conductive structures 330A-330C (collectively referred to as “conductive structures 330” or “conductive structure 330”), dielectric structures 340 (individually referred to as “dielectric structure 340”), dielectric structures 345 (individually referred to as “dielectric structure 345”), insulative structure 350, and another insulative structure 360. The IC device 300 may include different, fewer, or more components in other embodiments.

The semiconductor structures 310A, the semiconductor structure 320, the conductive structure 330A, the dielectric structures 340 and 345 connected to the conductive structure 330A, and the insulative structure 360 may be components of a transistor in the IC device 300. The semiconductor structures 310B, the conductive structures 330B and 330C, the dielectric structures 340 and 345 connected to the conductive structures 330B and 330C, and the insulative structure 350 are in the isolation region 305. A conductive structure 330 may include one or more conductive materials, such as polycrystalline silicon, metal, conductive nitrides, or other types of conductive materials. A dielectric structure 340 or 345 may include a dielectric material. In some embodiments, the dielectric structures 340 may include one or more high-k dielectric materials. The dielectric structures 340 and 345 may include the same materials. In some embodiments, the dielectric structures 345 may be used as hard masks. A dielectric structure 345 may include silicon nitride. The insulative structures 350 and 360 may include one or more electrical insulators. In some embodiments, the insulative structures 350 and 360 may be formed with the same electrical insulator.

In the embodiments of FIG. 3, the conductive structures 330B and 330C have different profiles from the conductive structure 330A due to the semiconductor cut. In some embodiments, the semiconductor cut is also referred to as fin cut. In some embodiments, the semiconductor cut and formation of the semiconductor structures 310A and 310B may be conducted before the conductive structures 330 are formed. Due to the semiconductor cut, the dimension of the semiconductor structures 310B along the Y axis is shorter than the dimension of the semiconductor structures 310A along the Y axis. Each of the semiconductor structures 310A extend across the entire conductive structure 330A, while the semiconductor structures 310B do not extend across the entire conductive structure 330B. Also, there are no semiconductor structures inside the conductive structure 330C. The differences in the distribution of semiconductor structures can cause WID variations between the conductive structures 330 and deteriorate the performance of the IC device 300.

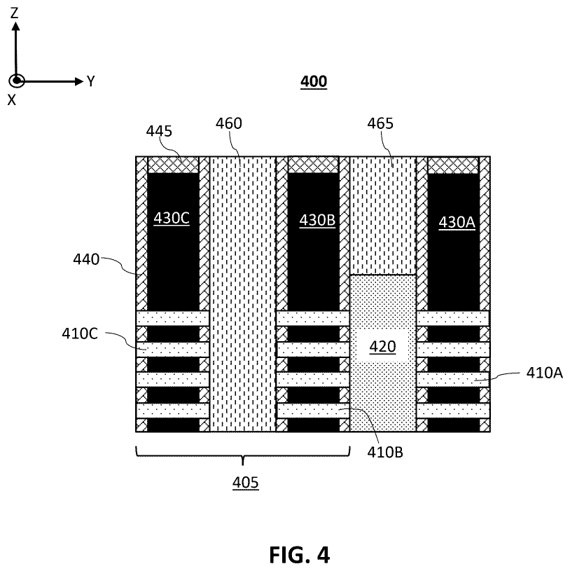

FIG. 4 illustrates an IC device 400 with no semiconductor cut in an isolation region 405, according to some embodiments of the disclosure. The IC device 400 includes semiconductor structures 410A (individually referred to as “semiconductor structure 410A”), semiconductor structures 410B (individually referred to as “semiconductor structure 410B”), semiconductor structures 410C (individually referred to as “semiconductor structure 410C”), another semiconductor structure 420, conductive structures 430A-430C (collectively referred to as “conductive structures 430” or “conductive structure 430”), dielectric structures 440 (individually referred to as “dielectric structure 440”), dielectric structures 445 (individually referred to as “dielectric structure 445”), insulative structure 450, and another insulative structure 460. The IC device 400 may include different, fewer, or more components in other embodiments. An example of the IC device 400 may be the IC device 100 or the IC device 200 in FIG. 2. For the purpose of illustration and simplicity, some components of the IC device 400 are not shown in FIG. 4.

The semiconductor structures 410A, the semiconductor structure 420, the conductive structure 430A, the dielectric structures 440 and 445 connected to the conductive structure 430A, and the insulative structure 460 may be components of a transistor in the IC device 400. The semiconductor structures 410B and 410C, the conductive structures 430B and 430C, the dielectric structures 440 and 445 connected to the conductive structures 430B and 430C, and the insulative structure 450 are in the isolation region 405. A conductive structure 430 may include one or more conductive materials, such as polycrystalline silicon, metal, conductive nitrides, or other types of conductive materials. A dielectric structure 440 or 450 may include a dielectric material. In some embodiments, the dielectric structures 440 may include one or more high-k dielectric materials. The dielectric structures 440 and 445 may include the same materials. In some embodiments, the dielectric structures 445 may be used as hard masks. A dielectric structure 445 may include silicon nitride. The insulative structures 450 and 460 may include one or more electrical insulators, e.g., low-k dielectric materials. In some embodiments, the insulative structures 450 and 460 may be formed with the same electrical insulator.

In the embodiments of FIG. 4, the conductive structures 430B and 430C have the same or substantially similar profiles from the conductive structure 430A as no semiconductor cut is conducted for the isolation region 405. As shown in FIG. 4, each of the semiconductor structures 410A extend across the entire conductive structure 430A. Similarly, each of the semiconductor structures 410B extend across the entire conductive structure 430B, and each of the semiconductor structures 410C extend across the entire conductive structure 430C. The consistency in the distribution of semiconductor structures can lead to consistency in profiles of the three conductive structures 430. The three conductive structures 430 may have the same or substantially similar contour, shape, dimension, etc. Compared with the IC device 300 in FIG. 3, the IC device 400 in FIG. 4 has less or even no WID variation caused by semiconductor cut and therefore, can have better performance.

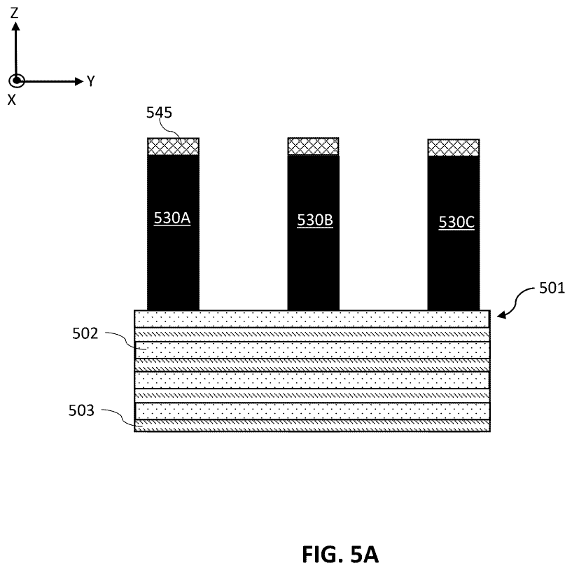

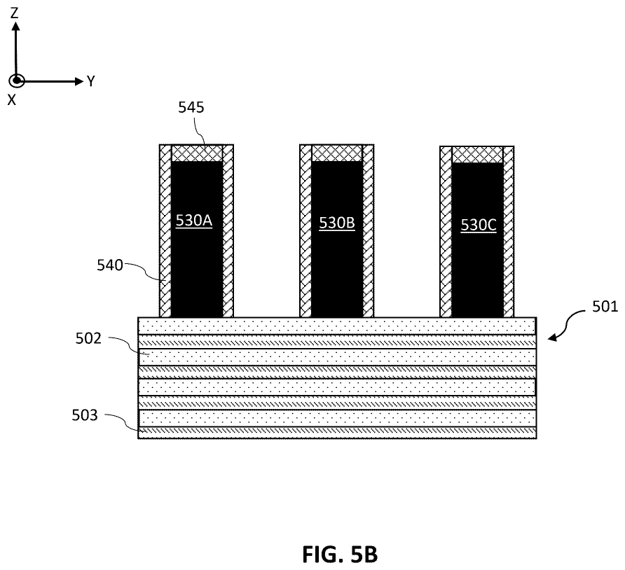

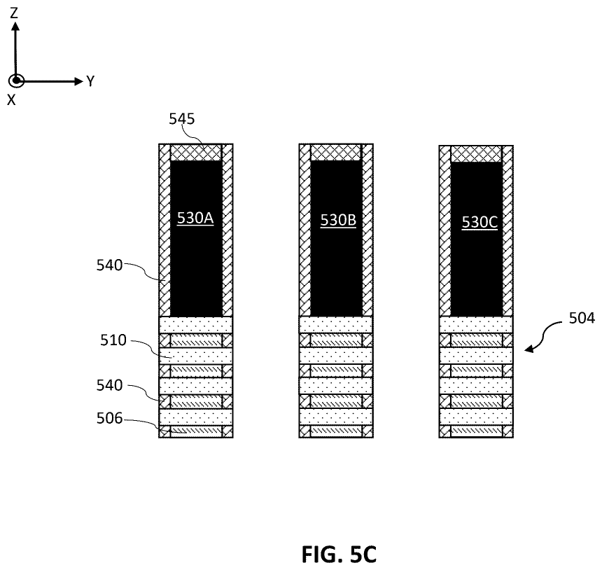

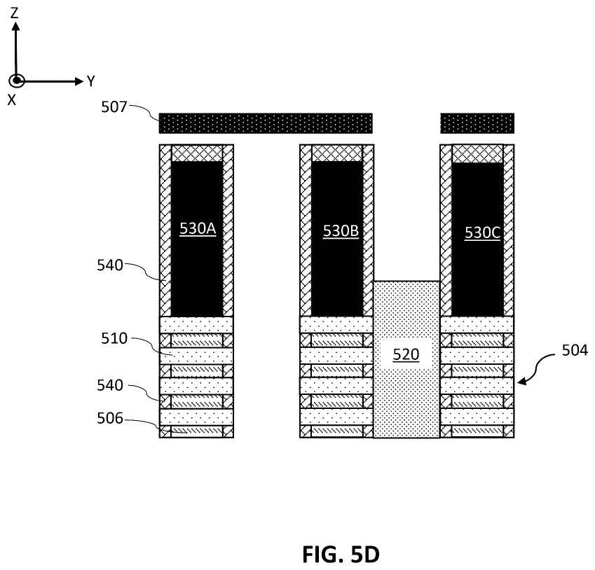

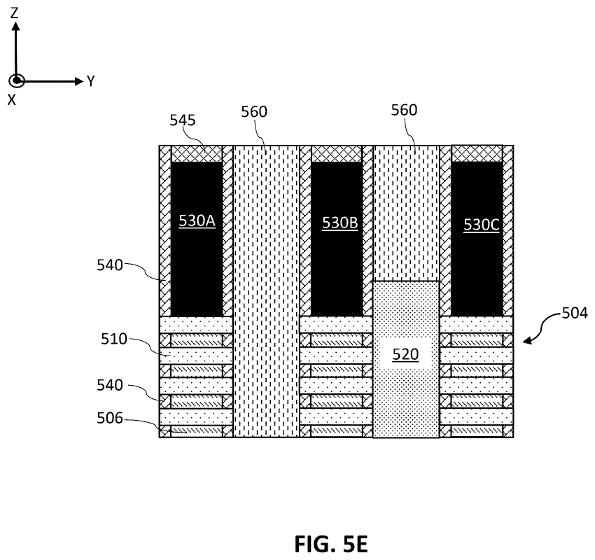

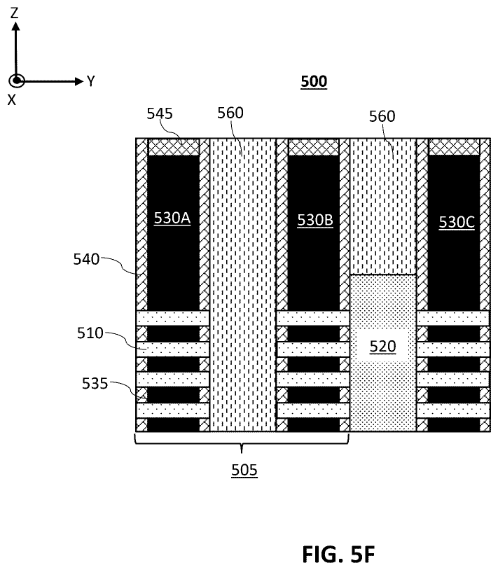

FIGS. 5A-5F illustrate a process of fabricating an IC device 500 with semiconductor structures 510 extending across gates in an isolation region 505, according to some embodiments of the disclosure. The IC device 500 may be an example of the IC device 400 in FIG. 4. Although the process is described with reference to the steps shown in FIGS. 5A-5F, many other processes for fabricating IC devices with semiconductor structures extending across gates in isolation regions may alternatively be used. For example, the order of execution of the steps shown in FIGS. 5A-5F may be changed. As another example, some of the steps may be changed, eliminated, or combined. For the purpose of illustration, some components of the IC device 500 are not shown in FIGS. 5A-5F.

In FIG. 5A, a semiconductor stack 501 is formed. The semiconductor stack 501 includes semiconductor structures 502 (individually referred to as “semiconductor structure 502”) alternating with semiconductor structures 503 (individually referred to as “semiconductor structure 503”). The semiconductor structures 502 and 503 are stacked in a direction along the Z axis. In some embodiments, a semiconductor structure 502 or 503 may be a fin or nanoribbon. The semiconductor structures 502 may include one or more channel materials. The semiconductor structures 503 may have one or more semiconductor materials that may be different from the channel materials.

Also, conductive structures 530A-530C (collectively referred to as “conductive structures 530” or “conductive structure 530”) and dielectric structures 545 (individually referred to as “dielectric structure 545”) are formed. The conductive structures 530 may be formed from one or more conductive materials, such as the conductive materials described above. The conductive structures 530 are parallel to each other along the X or Z axis. A conductive structure 530 may have a longitudinal axis along the X or Z axis. Each conductive structure 530 is between a portion of the semiconductor stack and a dielectric structure 545 along the Z axis. The dielectrics structures 545 may be formed from a dielectric material, e.g., silicon nitride, etc.

In FIG. 5B, dielectric layers 540 (individually referred to as “dielectric layer 540”) are formed. The dielectric layers 540 are over the semiconductor stack 501 along the Z axis. Each dielectric layer 540 wraps around a conductive structure 530 and the dielectric structure 545 connected to the conductive structure 530. The dielectric layers 540 may be formed from a dielectric material, which may be a high-k dielectric material.

In FIG. 5C, various portions of the semiconductor stack 501 are removed and three separate semiconductor stacks 504 (individually referred to as “semiconductor stack 504”) are formed. Each semiconductor stack 504 is over a conductive structure 530 and the dielectric layer 540 that wraps around the conductive structure 530. The conductive structure 530 and the dielectric layer 540 may constitute a gate. Each semiconductor stack 504 includes semiconductor structures 510 (individually referred to as “semiconductor structure 510”) and semiconductor structures 506 (individually referred to as “semiconductor structure 506”). Each semiconductor structure 510 is a portion of a semiconductor structure 502. Each semiconductor structure 510 extends at least from an edge of a conductive structure 530 to another edge of the conductive structure. The two edges oppose each other along the Y axis. For instance, each semiconductor structure 510 may extend across the entire gate including the corresponding conductive structure 530. In some embodiments, a first edge of the semiconductor structure 510 is aligned with a first edge of the gate along the Z axis, and a second edge of the semiconductor structure 510 is aligned with a second edge of the gate along the Z axis. The first edge opposes the second edge. Each semiconductor structure 506 is a portion of a semiconductor structure 503. Each semiconductor structure 506 is wrapped around by a dielectric layer 540.

In FIG. 5D, a semiconductor structure 520 is formed between the conductive structure 530B and the conductive structure 530C. The semiconductor structure 520 may be formed by depositing a semiconductor material into the opening region between the two conductive structures 530. The semiconductor material may be doped, e.g., with P-type dopants or N-type dopants. The semiconductor structure 520 may be a source or drain region of a transistor. In some embodiments, the semiconductor structure 520 may be formed through epitaxial growth of the semiconductor material. The semiconductor structure 520 may be an epitaxial structure. No semiconductor structure is formed between the conductive structure 530A and the conductive structure 530B. A mask 507 may be used for forming the semiconductor structure 520. As shown in FIG. 5D, the mask 507 has an opening that is aligned with the opening region between the conductive structure 530B and the conductive structure 530C so that the opening region is exposed. The mask 507 blocks other areas, including the opening region between the conductive structure 530A and the conductive structure 530B. Even though not shown in FIG. 5D, the mask may block other regions, e.g., a region for forming a source or drain of a transistor of an opposite type from the transistor including the semiconductor structure 520. The mask 507 may be removed after the semiconductor structure 520 is formed.

In FIG. 5E, an electrical insulator 560 is used to fill opening space between the conductive structures 530. The electrical insulator 560 may be deposited into the opening regions between the conductive structures 530. As shown in FIG. 5E, a portion of the electrical insulator 560 is between the conductive structures 530A and 530B and is over the semiconductor structure 520 along the Y axis. Another portion of the electrical insulator 560 is between the conductive structures 530B and 530C and is over the semiconductor structure 520 along the Z axis.

In FIG. 5F, the semiconductor structures 506 are replaced with conductive structures 535. The conductive structures 535 may have the same material as the conductive structures 530. In some embodiments, each conductive structure 530 and the conductive structures 535 over the conductive structure 530 may constitute a bigger conductive structure that can be used as a gate electrode. The bigger conductive structure and the corresponding dielectric layer 540 may constitute a gate. For instance, the conductive structurer 530C, the conductive structures 535 over the conductive structure 530C, and the dielectric layer 540 wrapping around the conductive structurer 530C and the conductive structures 535 may constitute the gate of the transistor having the semiconductor structure 520 as source or drain. The two gates including the conductive structures 530A and 530B may be used as dummy gates in the isolation region 505. As these two gates are formed in the same way as the gate including the conductive structurer 530C, the three gates can have the same or substantially similar profiles to avoid WID variations. The isolation of the transistor from other transistor can be achieved by avoiding formation of source or drain in the isolation region 505, e.g., by using the mask 507 in FIG. 5D.

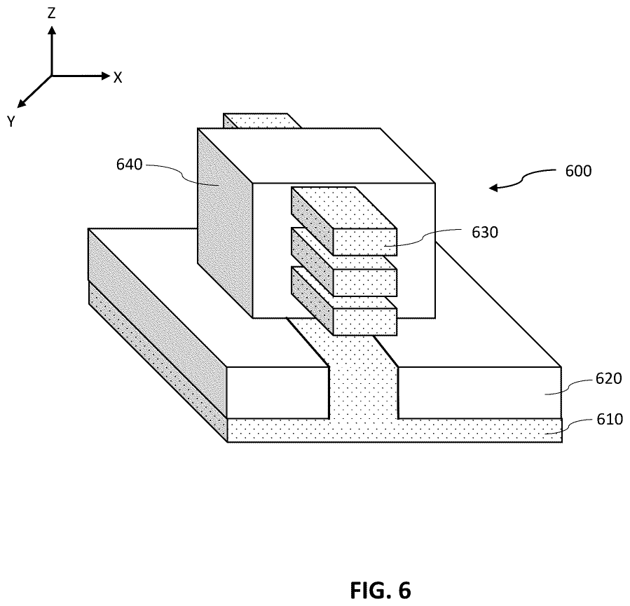

FIG. 6 shows nanoribbons 630 extending across a gate 640, according to some embodiments of the disclosure. The nanoribbons 630 (individually referred to as “nanoribbon 630”) may be examples of semiconductor structures 130 in FIG. 1, semiconductor structures 410A-410C in FIG. 4, and semiconductor structures 510 in FIG. 5. The gate 640 may be an example of the gates described in conjunction with FIG. 1, the gates 243, the gates 253, and the gates described in conjunction with FIGS. 4 and 5A-5F. In some embodiments, the nanoribbons 630 and gate 640 may be components of a transistor, such as the transistor 110 in FIG. 1, the transistors 240 and 250 in FIG. 2, and so on. The nanoribbons 630 and gate 640 are over a support structure 610 and a dielectric layer 620.

The support structure 610 may be any suitable structure, such as a substrate, a die, a wafer, or a chip, based on which semiconductor structures (e.g., the nanoribbons 630) can be formed. The support structure 610 may be an embodiment of the support structure 105 in FIG. 1. The dielectric layer 620 is over various portions of the support structure 610 along the Z axis. The dielectric layer 620 includes one or more dielectric materials, such as the dielectric materials described above.

The nanoribbons 630 are stacked over the support structure 610 along the Z axis. The nanoribbons 630 are arranged parallel to each other. Each nanoribbon 630 may have a longitudinal axis substantially parallel to the Y axis and a transverse cross-section substantially parallel to the X-Z plane. A dimension of a nanoribbon 630 along the Y axis may be greater than a dimension of the nanoribbon 630 in another direction. In other embodiments, each nanoribbon 630 may have a longitudinal axis substantially parallel to the X axis and a transverse cross-section substantially parallel to the Y-Z plane. A dimension of a nanoribbon 630 along the X axis may be greater than a dimension of the nanoribbon 630 in another direction.

The nanoribbons 630 may provide the channel region of at least one transistor. A channel region of a transistor may include a channel material, such as channel materials described above. Source or drain regions may be formed at ends of the nanoribbons 630. The source or drain regions may be connected to the nanoribbons 630. In some embodiments, a source or drain region may wrap around a portion of a nanoribbon 630. In an example, a source region and a drain region may be formed at opposite sides of the nanoribbons 630. The source region and drain region may each include a semiconductor material with dopants. In some embodiments, the source region and drain region have the same semiconductor material, which may be the same as the channel material of the channel region.

The dimensions of the nanoribbons 630 may be different for different applications of the transistor 600. For example, compared with embodiments where the transistor 600 is used in a memory die, the cross-section of each nanoribbon 630 in the X-Z plane may be larger when the transistor 600 is used in a logic die. The width of each nanoribbon 630 along the X axis may also be larger when the transistor 600 is used in a logic die. In some embodiments, the transistor 600 may be used in either a logic layer or a memory layer. A nanoribbon transistor in a logic layer may include more nanoribbons (e.g., approximately one to three times more) than a nanoribbon transistor in a memory layer. In some embodiments, the transistor 600 may be a transistor in a logic layer, and a transistor in a memory layer may be a FinFET.

The gate 640 is over the dielectric layer 620. In FIG. 6, the gate 640 wraps around the nanoribbons 630. The gate 640 and the nanoribbons 630 may form one or more GAA transistors. The gate 640 may include a gate electrode including one or more conductive materials, such as metal, polycrystalline silicon, other types of conductive materials, or some combination thereof. In some embodiments, the choice of the conductive materials in the gate 640 may depend on whether the transistor is a P-type transistor or an N-type transistor. For a P-type transistor, gate electrode materials that may be used in different portions of the gate electrode may include, but are not limited to, Ru, palladium, platinum, Co, nickel, and conductive metal oxides (e.g., ruthenium oxide). For an N-type transistor, gate electrode materials that may be used in different portions of the gate electrode, but are not limited to, hafnium, zirconium, titanium, tantalum, aluminium, alloys of these metals, and carbides of these metals (e.g., hafnium carbide, zirconium carbide, titanium carbide, tantalum carbide, and aluminium carbide).

In some embodiments, the gate 640 may include a stack of a plurality of gate electrode materials, where zero or more materials of the stack are work function materials and at least one material of the stack is a fill metal layer. Further materials/layers may be included next to the gate electrode for other purposes, such as to act as a diffusion barrier layer or/and an adhesion layer. The gate 640 may also include a gate insulator, part of which may be between the gate electrode and each nanoribbon 630. The gate 640 may be electrically coupled to a power plane, ground plane, or signal plane for facilitating power supply or signal transmission for the transistor 600.

FIGS. 7A-7B are top views of a wafer 2000 and dies 2002, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 8. The wafer 2000 may be composed of semiconductor material and may include one or more dies 2002 having IC devices formed on a surface of the wafer 2000. Each of the dies 2002 may be a repeating unit of a semiconductor product that includes any suitable IC (e.g., ICs with isolation regions including semiconductor structures extending across gates as described herein). After the fabrication of the semiconductor product is complete, the wafer 2000 may undergo a singulation process in which each of the dies 2002 is separated from one another to provide discrete “chips” of the semiconductor product. In particular, devices with semiconductor structures extending across gates in isolation regions as disclosed herein may take the form of the wafer 2000 (e.g., not singulated) or the form of the die 2002 (e.g., singulated). The die 2002 may include one or more diodes, one or more transistors as well as, optionally, supporting circuitry to route electrical signals to the III-N diodes with n-doped wells and capping layers and III-N transistors, as well as any other IC components. In some embodiments, the wafer 2000 or the die 2002 may implement an electrostatic discharge (ESD) protection device, a radio frequency front-end device, a memory device (e.g., a SRAM device), a logic device (e.g., an AND, OR, NAND, or NOR gate), or any other suitable circuit element. Multiple ones of these devices may be combined on a single die 2002.

FIG. 8 is a side, cross-sectional view of an example IC package 2200 that may include one or more IC devices with semiconductor structures extending across gates in isolation regions, according to some embodiments of the disclosure. In some embodiments, the IC package 2200 may be a system-in-package (SiP).

As shown in FIG. 8, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 8 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 8 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

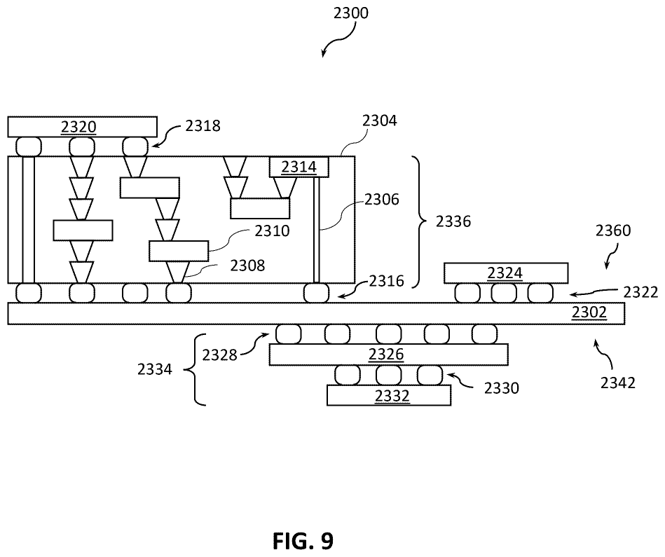

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 8 are solder balls (e.g., for a ball grid array arrangement), but any suitable second-level interconnects 2270 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 9.

The dies 2256 may take the form of any of the embodiments of the die 2002 discussed herein and may include any of the embodiments of an IC device with one or more semiconductor structures extending across a gate in an isolation region. In embodiments in which the IC package 2200 includes multiple dies 2256, the IC package 2200 may be referred to as a multi-chip package. Importantly, even in such embodiments of a multi-chip packaging (MCP) implementation of the IC package 2200, one or more IC devices with semiconductor structures extending across gates in isolation regions may be provided in a single chip, in accordance with any of the embodiments described herein. The dies 2256 may include circuitry to perform any desired functionality. For example, one or more of the dies 2256 may be ESD protection dies, including one or more IC devices with semiconductor structures extending across gates in isolation regions as described herein, one or more of the dies 2256 may be logic dies (e.g., silicon-based dies), one or more of the dies 2256 may be memory dies (e.g., high bandwidth memory), etc. In some embodiments, any of the dies 2256 may include or otherwise be associated with one or more components with semiconductor structures extending across gates in isolation regions, e.g., as discussed above; in some embodiments, at least some of the dies 2256 may not include any III-N diodes with n-doped wells and capping layers.

The IC package 2200 illustrated in FIG. 8 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 8, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 9 is a cross-sectional side view of an IC device assembly 2300 that may include components having one or more IC devices with semiconductor structures extending across gates in isolation regions, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC devices with semiconductor structures extending across gates in isolation regions in accordance with any of the embodiments disclosed herein; e.g., any of the IC packages discussed below with reference to the IC device assembly 2300 may take the form of any of the embodiments of the IC package 2200 discussed above with reference to FIG. 8 (e.g., may include one or more components with semiconductor structures extending across gates in isolation regions in/on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 9 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 9), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 7B), an IC device (e.g., the IC devices in FIGS. 1, 2, 4, and 5F), or any other suitable component. In particular, the IC package 2320 may include one or more devices with semiconductor structures extending across gates in isolation regions as described herein. Although a single IC package 2320 is shown in FIG. 9, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 9, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other Group III-V and Group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further RF (radio frequency) devices, power amplifiers, power management devices, antennas, arrays, sensors, and microelectromechanical systems (MEMS) devices may also be formed on the interposer 2304. In some embodiments, the IC devices with semiconductor structures extending across gates in isolation regions as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 9 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

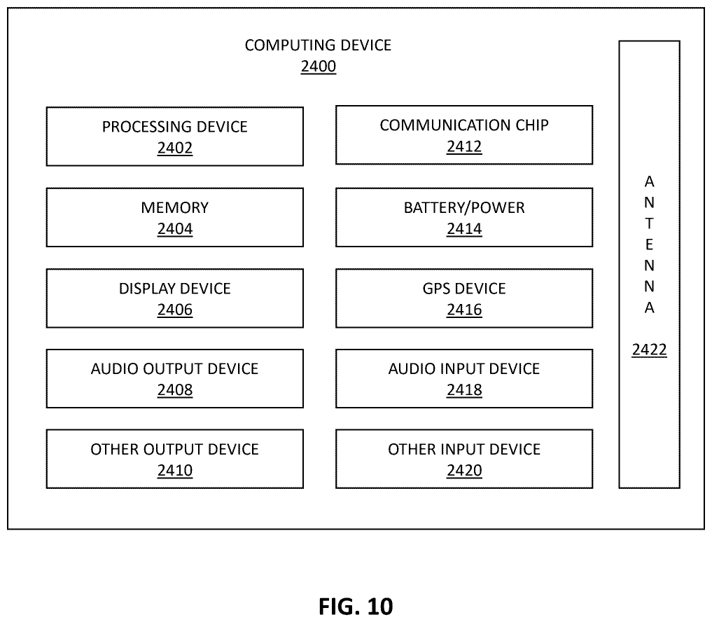

FIG. 10 is a block diagram of an example computing device 2400 that may include one or more components with one or more IC devices with semiconductor structures extending across gates in isolation regions, according to some embodiments of the disclosure. For example, any suitable ones of the components of the computing device 2400 may include a die (e.g., the die 2002 of FIG. 7B) including or associated with devices with semiconductor structures extending across gates in isolation regions, according to some embodiments of the disclosure. Any of the components of the computing device 2400 may include an IC device with one or more semiconductor structures extending across a gate in an isolation region (e.g., any embodiment of the IC devices described above in conjunction with FIGS. 1, 2 4, and 5F) and/or an IC package (e.g., the IC package 2200 of FIG. 8). Any of the components of the computing device 2400 may include an IC device assembly (e.g., the IC device assembly 2300 of FIG. 9).

A number of components are illustrated in FIG. 10 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC (system-on-chip) die.

Additionally, in various embodiments, the computing device 2400 may not include one or more of the components illustrated in FIG. 10, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., eDRAM, and/or spin transfer torque magnetic random-access memory (STT-MRAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices with semiconductor structures extending across gates in isolation regions as described herein may be particularly advantageous for use as part of ESD circuits protecting power amplifiers, low-noise amplifiers, filters (including arrays of filters and filter banks), switches, or other active components. In some embodiments, IC devices with semiconductor structures extending across gates in isolation regions as described herein may be used in PMICs, e.g., as a rectifying diode for large currents. In some embodiments, IC devices with semiconductor structures extending across gates in isolation regions as described herein may be used in audio devices and/or in various input/output devices.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include another output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include another input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

The following paragraphs provide various examples of the embodiments disclosed herein.

Example 1 provides an IC device, including a transistor including a semiconductor region, a gate electrode, the gate electrode having a first edge and a second edge opposing the first edge of the gate electrode, and a first semiconductor structure, the first semiconductor structure extending at least from the first edge of the gate electrode to the second edge of the gate electrode; a conductive structure parallel to the gate electrode, the conductive structure having a first edge and a second edge opposing the first edge of the conductive structure; a second semiconductor structure extending at least from the first edge of the conductive structure to the second edge of the conductive structure; and an electrical insulator, in which the semiconductor region is between the gate electrode and the conductive structure, and the conductive structure is between the electrical insulator and the first semiconductor structure.

Example 2 provides the IC device according to example 1, further including an additional conductive structure between the conductive structure and the gate electrode, the additional conductive structure having a first edge and a second edge opposing the first edge; and a third semiconductor structure extending at least from the first edge of the additional conductive structure to the second edge of the additional conductive structure, in which the electrical insulator is between the conductive structure and the additional conductive structure.

Example 3 provides the IC device according to example 2, in which the additional conductive structure is between the conductive structure and the gate electrode in a first direction, at least part of the electrical insulator is over the semiconductor region in a second direction, and the second direction is parallel to the first direction.

Example 4 provides the IC device according to any one of examples 1-3, in which the first semiconductor structure is in a channel region of the transistor, the channel region further includes one or more other semiconductor structures, each of which is parallel to the first semiconductor structure and crosses from the first edge of the gate electrode to the second edge of the gate electrode.

Example 5 provides the IC device according to any one of examples 1-4, in which the second semiconductor structure is in a group of semiconductor structures, and the group of semiconductor structure further includes one or more other semiconductor structures, each of which is parallel to the second semiconductor structure and crosses from the first edge of the conductive structure to the second edge of the conductive structure.

Example 6 provides the IC device according to any one of examples 1-5, further including a first dielectric layer wrapping around the gate electrode; and a second dielectric layer wrapping around the conductive structure.

Example 7 provides the IC device according to any one of examples 1-6, in which the gate electrode is coupled to a metal layer, and the conductive structure is separated from the metal layer by one or more electrical insulators.

Example 8 provides an IC device, including a first conductive structure, a second conductive structure, and a third conductive structure that are stacked over each other in a direction; a source or drain region of a transistor, in which the source or drain region is between the first conductive structure and the second conductive structure in the direction; a first semiconductor structure extending across the first conductive structure in the direction; a second semiconductor structure extending across the second conductive structure in the direction; and a third semiconductor structure extending across the third conductive structure in the direction.

Example 9 provides the IC device according to example 8, further including a fourth conductive structure connected to the first conductive structure, the fourth conductive structure having a longitudinal axis in another direction that is perpendicular to the direction.

Example 10 provides the IC device according to example 9, further including a metal layer connected to the fourth conductive structure, in which the metal layer is separated from the second conductive structure and from the third conductive structure by one or more electrical insulators.

Example 11 provides the IC device according to any one of examples 8-10, further including a fourth conductive structure connected to the source or drain region, the fourth conductive structure separated from the first conductive structure by one or more electrical insulators.

Example 12 provides the IC device according to any one of examples 8-11, further including a dielectric structure between the second conductive structure and the third conductive structure in the direction, in which at least part of the dielectric structure is over the source or drain region in the direction.

Example 13 provides the IC device according to any one of examples 8-12, in which the first conductive structure is a gate electrode of the transistor.

Example 14 provides the IC device according to any one of examples 8-13, in which each of the first conductive structure, the second conductive structure, and the third conductive structure is wrapped around by a dielectric layer.

Example 15 provides a method of forming an IC device, the method including forming a group of conductive structures and a stack of semiconductor structures, the conductive structure stacked over each other, a semiconductor structure extending across the group of conductive structures; removing a first portion of the stack of semiconductor structures to form a first opening region between a first conductive structure in the group and a second conductive structure in the group; removing a second portion of the stack of semiconductor structures to form a second opening region between the second conductive structure in the group and a third conductive structure in the group; forming a semiconductor region in the first opening region; and forming an electrical insulator in the second opening region.

Example 16 provides the method according to example 15, further including after forming the group of conductive structures and the stack of semiconductor structures, forming dielectric layers, a dielectric layer wrapping around a conductive structure in the group.

Example 17 provides the method according to example 15 or 16, in which the semiconductor structures in the stack are separated from each other by other semiconductor structures.

Example 18 provides the method according to example 17, further including after forming the electrical insulator, replacing the other semiconductor structures with additional conductive structures.

Example 19 provides the method according to any one of examples 15-18, in which forming the semiconductor region in the first opening region includes applying a mask that exposes the first opening region and blocks the second opening region; and depositing a semiconductor material into the first opening region through the mask.

Example 20 provides the method according to any one of examples 15-19, further including forming another conductive structure over the semiconductor region.

Example 21 provides an IC package, including the IC device according to any one of examples 1-20; and a further IC component, coupled to the device.

Example 22 provides the IC package according to example 21, where the further IC component includes one of a package substrate, an interposer, or a further IC die.

Example 23 provides the IC package according to example 21 or 22, where the IC device according to any one of examples 1-20 may include, or be a part of, at least one of a memory device, a computing device, a wearable device, a handheld electronic device, and a wireless communications device.

Example 24 provides an electronic device, including a carrier substrate; and one or more of the IC devices according to any one of examples 1-20 and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

Example 34 provides processes for forming the IC device according to any one of claims 1-20.

Example 35 provides processes for forming the IC package according to any one of the claims 21-23.

Example 36 provides processes for forming the electronic device according to any one of the claims 24-33.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a transistor comprising:
a semiconductor region,
a gate electrode, the gate electrode having a first edge and a second edge opposing the first edge of the gate electrode, and
a first semiconductor structure, the first semiconductor structure extending at least from the first edge of the gate electrode to the second edge of the gate electrode;
a conductive structure parallel to the gate electrode, the conductive structure having a first edge and a second edge opposing the first edge of the conductive structure;
a second semiconductor structure extending at least from the first edge of the conductive structure to the second edge of the conductive structure; and
an electrical insulator,
wherein the semiconductor region is between the gate electrode and the conductive structure, and the conductive structure is between the electrical insulator and the first semiconductor structure.

2. The IC device according to claim 1, further comprising:
an additional conductive structure between the conductive structure and the gate electrode, the additional conductive structure having a first edge and a second edge opposing the first edge; and
a third semiconductor structure extending at least from the first edge of the additional conductive structure to the second edge of the additional conductive structure,
wherein the electrical insulator is between the conductive structure and the additional conductive structure.

3. The IC device according to claim 2, wherein the additional conductive structure is between the conductive structure and the gate electrode in a first direction, at least part of the electrical insulator is over the semiconductor region in a second direction, and the second direction is parallel to the first direction.

4. The IC device according to claim 1, wherein the first semiconductor structure is in a channel region of the transistor, the channel region further includes one or more other semiconductor structures, each of which is parallel to the first semiconductor structure and crosses from the first edge of the gate electrode to the second edge of the gate electrode.

5. The IC device according to claim 1, wherein the second semiconductor structure is in a group of semiconductor structures, and the group of semiconductor structure further includes one or more other semiconductor structures, each of which is parallel to the second semiconductor structure and crosses from the first edge of the conductive structure to the second edge of the conductive structure.

6. The IC device according to claim 1, further comprising:
a first dielectric layer wrapping around the gate electrode; and
a second dielectric layer wrapping around the conductive structure.

7. The IC device according to claim 1, wherein the gate electrode is coupled to a metal layer, and the conductive structure is separated from the metal layer by one or more electrical insulators.

8. An integrated circuit (IC) device, comprising:
a first conductive structure, a second conductive structure, and a third conductive structure that are stacked over each other in a direction;
a source or drain region of a transistor, wherein the source or drain region is between the first conductive structure and the second conductive structure in the direction;
a first semiconductor structure extending across the first conductive structure in the direction;
a second semiconductor structure extending across the second conductive structure in the direction; and
a third semiconductor structure extending across the third conductive structure in the direction.

9. The IC device according to claim 8, further comprising:
a fourth conductive structure connected to the first conductive structure, the fourth conductive structure having a longitudinal axis in another direction that is perpendicular to the direction.

10. The IC device according to claim 9, further comprising:
a metal layer connected to the fourth conductive structure,
wherein the metal layer is separated from the second conductive structure and from the third conductive structure by one or more electrical insulators.

11. The IC device according to claim 8, further comprising:
a fourth conductive structure connected to the source or drain region, the fourth conductive structure separated from the first conductive structure by one or more electrical insulators.

12. The IC device according to claim 8, further comprising:
a dielectric structure between the second conductive structure and the third conductive structure in the direction,
wherein at least part of the dielectric structure is over the source or drain region in the direction.

13. The IC device according to claim 8, wherein the first conductive structure is a gate electrode of the transistor.

14. The IC device according to claim 8, wherein each of the first conductive structure, the second conductive structure, and the third conductive structure is wrapped around by a dielectric layer.

15. A method of forming an integrated circuit (IC) device, the method comprising:
forming a group of conductive structures and a stack of semiconductor structures, the conductive structure stacked over each other, a semiconductor structure extending across the group of conductive structures;
removing a first portion of the stack of semiconductor structures to form a first opening region between a first conductive structure in the group and a second conductive structure in the group;
removing a second portion of the stack of semiconductor structures to form a second opening region between the second conductive structure in the group and a third conductive structure in the group;
forming a semiconductor region in the first opening region; and
forming an electrical insulator in the second opening region.

16. The method according to claim 15, further comprising:
after forming the group of conductive structures and the stack of semiconductor structures, forming dielectric layers, a dielectric layer wrapping around a conductive structure in the group.

17. The method according to claim 15, wherein the semiconductor structures in the stack are separated from each other by other semiconductor structures.

18. The method according to claim 17, further comprising:
after forming the electrical insulator, replacing the other semiconductor structures with additional conductive structures.

19. The method according to claim 15, wherein forming the semiconductor region in the first opening region comprises:
applying a mask that exposes the first opening region and blocks the second opening region; and
depositing a semiconductor material into the first opening region through the mask.

20. The method according to claim 15, further comprising:
forming another conductive structure over the semiconductor region.
